(19) United States
(12) Patent Application Publication
(10) Pub. No.: US 2005/0093652 A1
(43) Pub. Date: May 5, 2005

(54) Size scaling of film bulk acoustic resonator (FBAR) filters using impedance transformer (IT) or balun

(76) Inventors: Qing Ma, San Jose, CA (US); Dong S. Shim, San Jose, CA (US)

Correspondence Address: Tood M. Becker;BLAKELY, SOKOLOFF, TAYLOR & ZAFMAN LLP, Seventh Floor, 12400 Willshire Boulevard, Los Angeles, CA, 90025-1026, US

(21) Appl. No.: 10/698,889

(22) Filed: Oct. 31, 2003

(51) Int. Cl. H03H 9/58

(52) U.S. Cl. 333/187; 333/189

(57) ABSTRACT

The disclosure describes an apparatus comprising a film bulk acoustic resonator (FBAR) filter having an input and an output, and an impedance matching unit coupled to one of the input and the output of the FBAR filter. Also described is a process comprising providing a film bulk acoustic resonator (FBAR) filter, the FBAR filter having an input impedance and an output impedance, matching the impedance of an input circuit to the input impedance of the FBAR filter, and matching the output impedance of the FBAR filter to the impedance of an output circuit. Other embodiments are described and claimed.

### TECHNICAL FIELD

The present invention relates generally to film bulk acoustic resonators (FBARs) and in particular, but not exclusively, to scaling the size of an FBAR filter while matching its impedance to the impedance of a circuit or network with which it is connected.

### BACKGROUND

Front-end radio frequency (RF) filters consisting of film bulk acoustic resonators (FBAR) have many advantages compared to other technologies, such as SAW devices and ceramic filters, particularly at high frequencies. For example, SAW filters start to have excessive insertion loss above 2.4 GHz, and ceramic filters are much larger in size and becomes increasingly difficult to fabricate as frequency increases. One limitation of FBAR technology, however, is that a filter's characteristic impedance is determined by the size of the resonators, which in turn is determined by a variety of design factors, such as the power-handling requirements, the required passband and stopband, and the amount of rejection required. More specifically, the impedance is inversely proportional to the active area of the device. An FBAR filter used in a circuit of specific impedance is therefore not scalable in size because its impedance will change as soon as its active area changes. However, it is often desirable or necessary to scale the size.

One approach to scaling the size of an FBAR filter has been to use the technique of increasing electrode thickness and reducing thickness of the piezoelectric membrane to increase unit area capacitance, therefore reducing size. Unfortunately, this technique requires processing technology development and it reduces the electrical-mechanical coupling coefficient and therefore limits filter pass bandwidth. Another technique that has been tried is to double the resonator area size for power handling, and then put two sets of resonators in series to bring back the impedance. This technique increases the insertion loss.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a side elevation drawing of a film bulk acoustic resonator (FBAR).

FIG. 2 is a schematic drawing of a ladder-type FBAR filter.

FIG. 3 is a schematic drawing of a lattice-type FBAR filter.

FIGS. 4A-4B are schematics showing one-sided impedance matching of an FBAR filter.

FIG. 4C is a schematic showing two-sided impedance matching of an FBAR filter.

FIGS. 5A-5D are schematics of embodiments of an impedance matching unit that can be used as shown in FIGS. 4A-4C.

FIGS. 6A-6B are schematics of additional embodiments of impedance matching units that can be used as shown in FIGS. 4A-4C.

FIGS. 7A-7B are schematics of further additional embodiments of impedance matching units that can be used as shown in FIGS. 4A-4C.

FIG. 8 is a schematic of another alternative embodiment of an impedance matching unit comprising a balanced/unbalanced (or “balun”) circuit that can be used as shown in FIGS. 4A-4C when balanced output is required from the filter.

### DETAILED DESCRIPTION OF THE ILLUSTRATED EMBODIMENTS

Embodiments of an apparatus and method for scaling the size of a film bulk acoustic resonator (FBAR) and matching its impedance using an impedance matching unit are described herein. In the following description, numerous specific details are described to provide a thorough understanding of embodiments of the invention. One skilled in the relevant art will recognize, however, that the invention can be practiced without one or more of the specific details, or with other methods, components, materials, etc. In some instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the invention. Thus, appearances of the phrases “in one embodiment” or “in an embodiment” in this specification do not necessarily all refer to the same embodiment. Furthermore, the particular features, structures, or characteristics may be combined in any suitable manner in one or more embodiments.

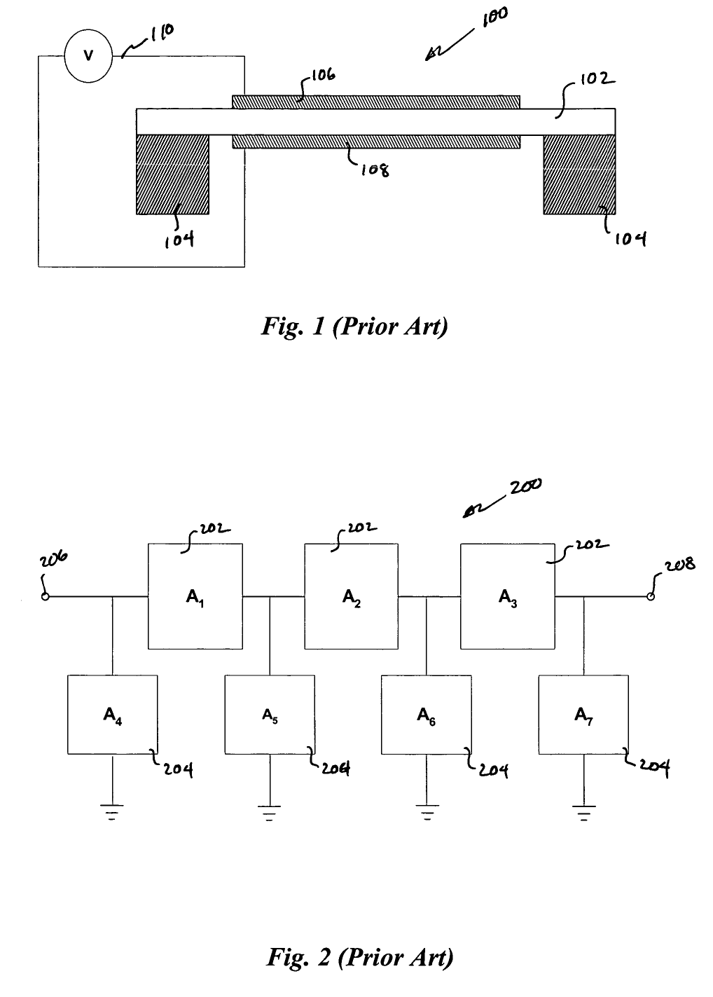

FIG. 1 illustrates a film bulk acoustic resonator (FBAR) 100. The FBAR 100 comprises a piezoelectric membrane 102 suspended along its edges by supports 104. The supports 104 suspend the membrane 102 above a substrate (not shown), thus creating a cavity between the membrane and the substrate; the presence of this cavity between membrane and substrate allows the free vibration of the membrane. The piezoelectric membrane 102 comprises a piezoelectric material such as Aluminum Nitride (AlN), a portion of which is sandwiched between a first electrode (in this instance the upper electrode 106) and a second electrode (in this instance the lower electrode 108). The effective area of each FBAR is the portion of the piezoelectric membrane between the first and second electrodes, because only the area between the electrodes can be subjected to an applied electric field. When a voltage V is applied to the electrodes using means such as circuit 110, the membrane vibrates. The resonant frequency of the membrane is proportional to the ratio v/2d, where v is the average propagation velocity of the acoustic wave and d is the thickness of the FBAR. The electrical impedance of an FBAR is inversely proportional to its effective area: if an FBAR with an effective area A has impedance Z₀, then an FBAR with effective area αA will have impedance Z₀/α.

FIG. 2 illustrates an embodiment of an FBAR filter 200. The FBAR filter 200 is a ladder-type filter comprising several individual FBARs 202 coupled in series between an input 206 and an output 208. In addition to the series FBARs 202, the filter 200 includes a plurality of shunt FBARs 204. The shunt FBARs 204 are connected between the series FBARs 202, as well as between the input 206 and the first series FBAR 202 and between the last series FBAR 202 and the output 208. The shunt FBARs are also connected to ground. In one embodiment, all the series FBARs have the same resonant frequency and all the shunt FBARs have the same resonant frequency, although the resonant frequency of the series FBARs can be different than the resonant frequency of the shunt FBARs. Each series FBAR 202 and shunt FBAR 204 has an area Aᵢ, and the areas Aᵢ of the FBARs can be the same or different than other FBARs. For example, in the embodiment shown, one series FBAR 202 has an area A₃, which can be the same or different than the area A₂ of the neighboring series FBAR 202, which in turn can be the same or different than the area A₁ of its neighboring series FBAR. Other embodiments of a ladder-type FBAR can include more or less series FBARs 202 and shunt FBARs 204.

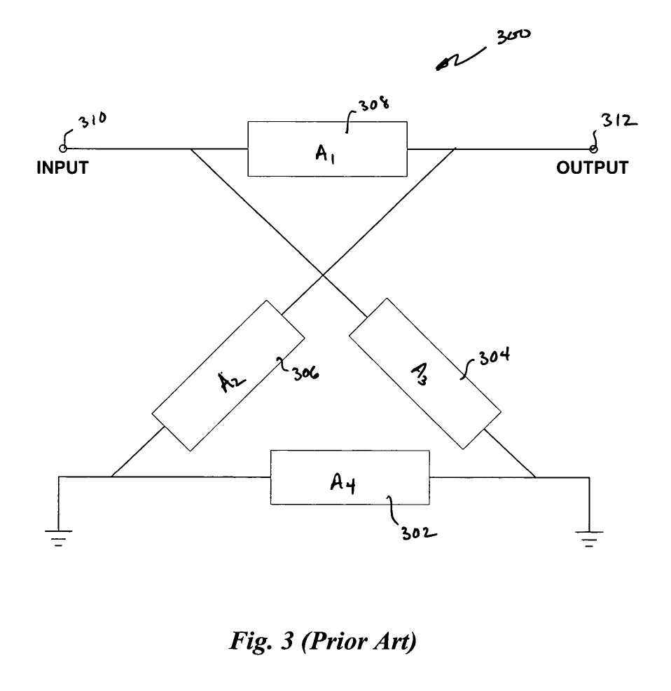

FIG. 3 illustrates an alternative embodiment of an FBAR filter 300. The filter 300 is a lattice-type filter comprising a plurality of individual FBARs in a lattice structure. The filter 300 comprises an FBAR 302 in series between a pair of grounds and an FBAR 308 in series between an input 310 and an output 312. An FBAR 304 is connected between the input 310 and the FBAR 308, as well as between the FBAR 302 and ground. Similarly, an FBAR 306 is connected between the FBAR 308 and the output 312, as well as between the FBAR 302 and ground. As with the ladder-type FBAR filter 200, each FBAR has an area Aᵢ, and the areas Aᵢ of the FBARs can be the same or different than other FBARs.

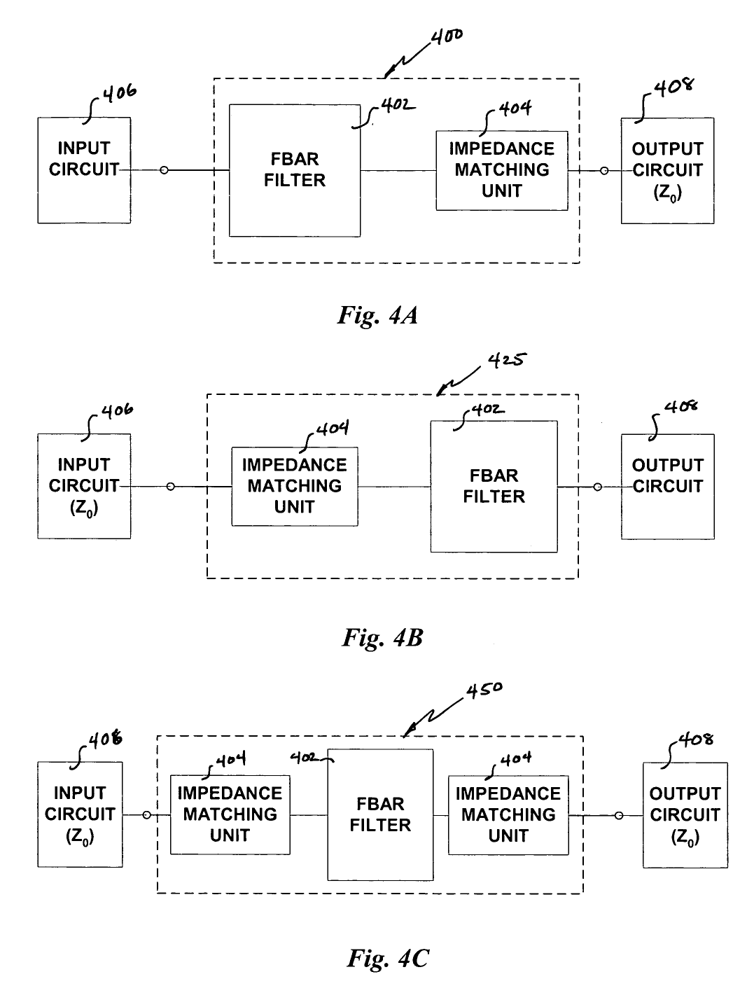

FIGS. 4A-4C illustrate embodiments of impedance-matched FBAR filters. FIG. 4A illustrates a filter 400 with one-sided impedance matching at its output. The filter 400 comprises an FBAR filter 402 whose output is coupled to an impedance matching unit 404. An input circuit 406 is coupled to the input of the filter 400 (and thus to the input of the FBAR filter 402), while an output circuit 408 is coupled to the output of the impedance matching unit 404. The FBAR filter 402 has an area αA, where A is the area of the FBAR filter that would result in an impedance Z₀ equal to the impedance of the output circuit 408, and α is a scaling factor that determines whether the area of the FBAR filter is less than A (i.e., α<1) or greater than A (i.e., α>1). The one-sided impedance matching matches the output impedance of the FBAR filter 402—and thus the output impedance of the filter 400—to the impedance Z₀ of the output circuit 408.

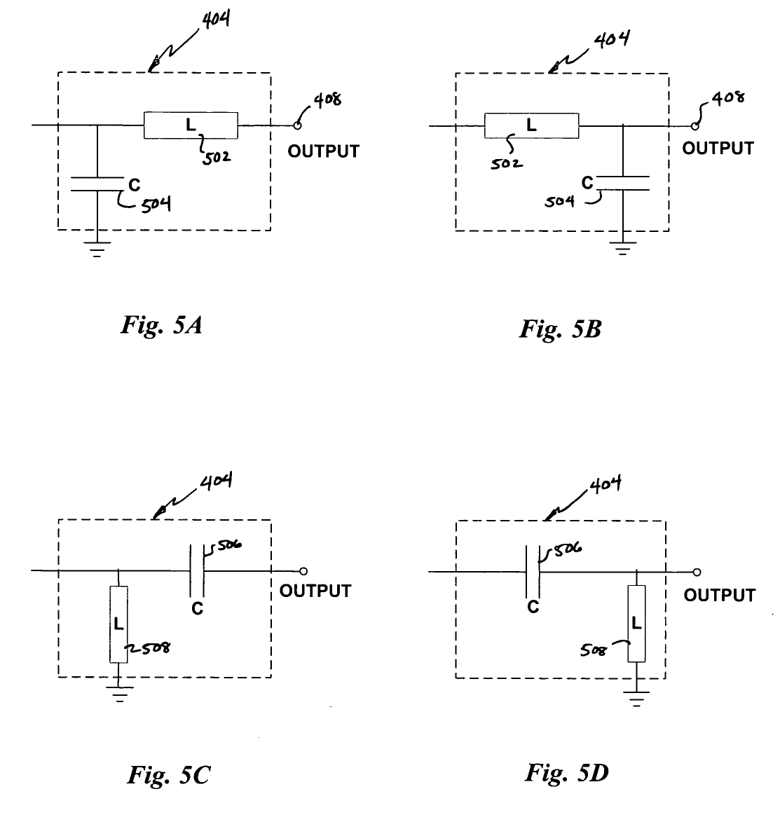

In operation of the filter 400, the FBAR filter 402 is only impedance-matched on one side, since the goal is to match the impedance of the filter 400 to the impedance of the output circuit 408. The FBAR filter 402 has an area αA, meaning that the FBAR 402 has an impedance of Z₀/α. The impedance matching unit 404 therefore scales the impedance Z₀/α of the FBAR filter 402 by a factor of α, so that the impedance at the output of the filter 400 matches the impedance Z₀ of the output circuit 408. Embodiments of impedance matching units 404 that can accomplish the proper impedance scaling are described below in connection with FIGS. 5A-5D, 6A-6B and 7A-7B. Although the output impedance of the filter 400 matches the impedance of the output circuit 408, the impedance of the input circuit 406 may or may not match the impedance at the input of the filter 400. In cases where there is an impedance mismatch, the input circuit can be designed or re-designed, as the case may be, to match the impedance of the FBAR filter 402.

FIG. 4B illustrates an impedance-matched filter 425 with one-sided impedance matching at the input instead of at the output as in the filter 400. The filter 425 comprises an FBAR filter 402 whose input is coupled to an impedance matching unit 404. An input circuit 406 is coupled to the input of the filter 425 (and thus to the input of the impedance matching unit 404), while an output circuit 408 is coupled to the output of the filter 425, and thus to the output of the FBAR filter 402. As before, the FBAR filter 402 has an area αA, where A is the area of the FBAR filter that would result in an impedance equal to the impedance Z₀ of the input circuit 406, and α is a scaling factor that determines whether the area of the FBAR filter is less than A (i.e., α<1) or greater than A (i.e., α>1). The one-sided impedance matching matches the input impedance of the FBAR filter 402—and thus the input impedance of the filter 425—to the impedance Z₀ of the input circuit 406.

In operation of the filter 425, the FBAR filter 402, the goal is to match the impedance of the filter 425 to the impedance of the input circuit 406. As in the filter 400, the FBAR filter 402 has an area αA, meaning that the FBAR 402 has an impedance of Z₀/α. The impedance matching unit 404 therefore scales the impedance Z₀ of the input circuit 406 by a factor of 1/α to match the impedance Z₀/α of the FBAR filter 402. Although the input impedance of the filter 425 matches the impedance of the input circuit 406, the impedance of the output circuit 408 may or may not match the output impedance of the filter 425. In some cases, such as when the output of the filter 425 is used to drive an antenna, impedance matching is not necessary. In cases where impedance matching with the output circuit 408 is necessary, the output circuit can be designed or re-designed, as the case may be, to match the impedance of the FBAR filter 402.

FIG. 4C illustrates an impedance-matched filter 450 with two-sided impedance matching. The filter 450 comprises an FBAR filter 402 whose input and output are coupled to impedance matching units 404. An input circuit 406 is coupled to the input of the filter 450 (and thus to the input impedance matching unit 404), and an output circuit 408 is coupled to the output of the filter 450 (and thus to the output impedance matching unit 404). As in previous embodiments, the FBAR filter 402 has an area αA, where A is the area of the FBAR filter that would result in an impedance Z₀ equal to the impedances of the input and output circuits, and α is a scaling factor that determines whether the area of the FBAR filter is less than A (i.e., α<1) or greater than A (i.e., α>1). The filter 450 matches the impedances at the input and output of the FBAR filter 402—and thus the impedances at the input and output of the filter 450—to the impedances of the input circuit 406 and the output circuit 408. In the embodiment shown, the impedance matching is symmetrical, meaning that the impedance Z₀ is the same for both the input circuit 406 and the output circuit 408, and that the increase (or decrease) in impedance caused by the impedance matching unit at the input is equal to the decrease (or increase) in impedance caused by the impedance matching unit 404 at the output. In other embodiments the impedance matching can be non-symmetrical.

In operation of the filter 450, the FBAR filter 402 the goal is to match the impedance of the filter 450 to the impedance of the input circuit 406 and the output circuit 408. The FBAR filter 402 has an area αA, meaning that the FBAR 402 has an impedance of Z₀/α. The impedance matching unit 404 at the input therefore scales the impedance Z₀ of the input circuit 406 by a factor of 1/α to match the impedance of the FBAR filter 402. Similarly, the impedance matching unit 404 at the output scales the impedance Z₀/α of the FBAR filter 402 by a factor of α to match the impedance of the output circuit.

FIGS. 5A-5D illustrate embodiments of impedance matching units 404 that can be used in the filter embodiments 400, 425 and 450 shown in FIGS. 4A-4C. FIG. 5A illustrates an embodiment comprising a shunt capacitor 504 followed by an in-line inductor 502. The capacitance C of the shunt capacitor 504 and the inductance L of the inductor 502 are determined by solving the equation

$$\frac{α}{{Z}_{0}^{*}} = \frac{1}{{Z}_{0} + ⅈ ω L} + ⅈ ω C ,$$

where α is the area scaling factor of the FBAR, Z*₀ is the complex conjugate of Z₀, Z₀ is the impedance to be matched (i.e., the impedance of the input or output circuit, as the case may be), i is the square root of −1, ω is the signal frequency, L is the inductance and C is the capacitance. This embodiment of the impedance matching unit is suitable for use in situations where the scaling factor α is less than one—that is, where the FBAR filter 402 has a lower impedance than the circuits to which it can be connected. This embodiment is also most suitable for use with FBAR filters 402 that attenuate high frequencies, since the shunt capacitor and the in-line inductor both attenuate high frequencies.

FIG. 5B illustrates an embodiment similar to the embodiment of FIG. 5A, except that the position of the shunt capacitor is changed, so that this embodiment comprises an in-line inductor 502 followed by a shunt capacitor 504. The capacitance C of the shunt capacitor 504 and the inductance L of the inductor 502 in this embodiment are determined by solving the equation

$$\frac{{Z}_{0}^{*}}{α} = \frac{1}{1 / {Z}_{0} + ⅈ ω C} + ⅈω L .$$

This embodiment is suitable for use in situations where the scaling factor α is greater than one—that is, where the FBAR filter has higher impedance than the circuits to which it can be connected. As with the embodiment shown in FIG. 5A, this embodiment is suitable for use with FBAR filters 402 that attenuate high frequencies, since the shunt capacitor and the in-line inductor both attenuate high frequencies.

FIG. 5C illustrates an embodiment similar to the embodiment of FIG. 5A, except that the positions of the capacitor and inductor are transposed. This embodiment, then, comprises a shunt inductor 508 followed by an in-line capacitor 504. The capacitance C of the shunt capacitor 504 and the inductance L of the inductor 502 are determined by solving the equation

$$\frac{α}{{Z}_{0}^{*}} = \frac{1}{{Z}_{0} + 1 / ⅈ ω C} + \frac{1}{ⅈ ω L} .$$

This embodiment is suitable for use in situations where the scaling factor α is less than one—that is, where the FBAR filter 402 has lower impedance than the circuits to which it can be connected. This embodiment is most suitable for use with FBAR filters 402 that attenuate low frequencies, since the shunt inductor and the in-line capacitor both attenuate lower frequencies.

FIG. 5D illustrates an embodiment similar to the embodiment of FIG. 5C, except that the position of the shunt inductor is changed. This embodiment, then, comprises an in-line capacitor 504 followed by a shunt inductor 508. The capacitance C of the shunt capacitor 504 and the inductance L of the inductor 502 are determined by solving the equation

$$\frac{{Z}_{0}^{*}}{α} = \frac{1}{1 / {Z}_{0} + 1 / ⅈ ω L} + \frac{1}{ⅈ ω C} .$$

This embodiment is most suitable for use in situations where the scaling factor α is greater than one—that is, where the FBAR filter 402 has higher impedance than the circuits to which it can be connected. This embodiment is suitable for use with FBAR filters 402 that attenuate low frequencies, since the shunt inductor and the in-line capacitor both attenuate lower frequencies.

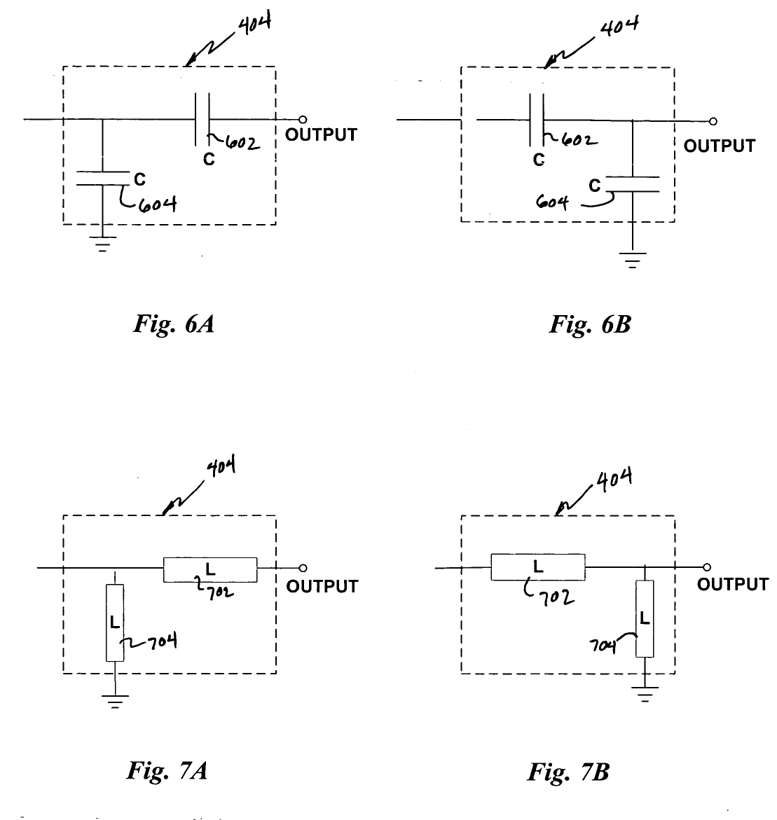

FIGS. 6A-6B illustrate additional embodiments of the impedance matching unit 404 that can be used in the filters 400, 425 and 450. FIG. 6A illustrates an embodiment of an impedance matching unit 404 that includes a shunt capacitor 604 followed by an in-line capacitor 602. Similarly, FIG. 6B illustrates an embodiment of an impedance matching unit 404 that includes an in-line capacitor 602 followed by a shunt capacitor 604. For the embodiments shown in FIGS. 6A and 6B, the capacitances C of the capacitors 602 and 604 are determined by solving equations similar in form to those shown above in connection with the embodiments in FIGS. 5A-5D; these equations can easily be derived and solved by those skilled in the art.

FIGS. 7A-7B illustrate alternative embodiments of the impedance matching unit 404 that can be used in the filters 400, 450 and 450. FIG. 7A illustrates an embodiment of an impedance matching unit 404 that includes a shunt inductor 604 followed by an in-line inductor 602. Similarly, FIG. 7B illustrates an embodiment of an impedance matching unit 404 that includes an in-line inductor 602 followed by a shunt inductor 604. For the embodiments shown in FIGS. 7A and 6B, the inductances L of the inductors 602 and 604 are determined by solving equations similar in form to those shown above in connection with the embodiments in FIGS. 5A-5D; these equations can easily be derived and solved by those skilled in the art.

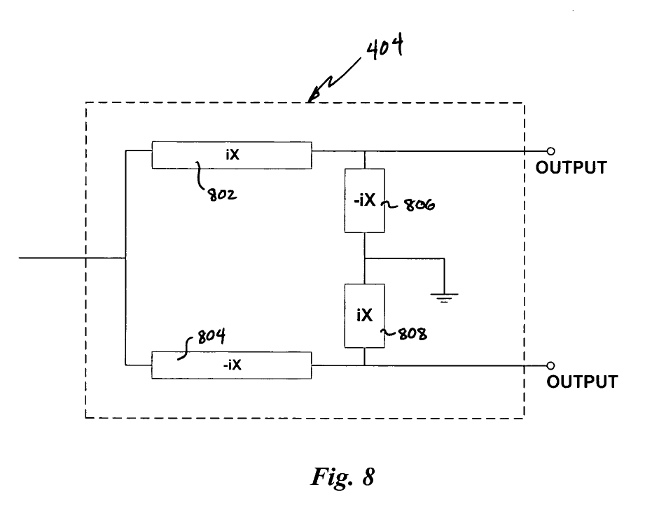

FIG. 8 illustrates yet another alternative embodiment of the impedance matching unit 404 that can be used in the filters 400, 425 and 450. The impedance matching unit 404 shown in FIG. 8 is an embodiment of a balanced/unbalanced circuit, also commonly known in the art as a “balun” circuit. In many applications, the output form a filter must be differential to reduce noise. Baluns are often used to transform a single filter output into a balanced differential output. The balun shown in FIG. 8 comprises a pair of elements 802 and 804 connected in parallel to the output of the FBAR filter 402. The elements are denoted generally by the letter X, because they can be any of several elements. In one particular embodiment, the elements 802 and 804 will be a capacitor and an inductor, or vice versa, so that

$$\begin{matrix}\vert X \vert = ω L or \\ \vert X \vert = \frac{1}{ω C} ,\end{matrix}$$

as the case may be. A pair of elements 806 and 808 are connected in series between the output of the element 802 and the output of the element 804; as with elements 802 and 804, the elements 806 and 808 are denoted with the letter X and will be a capacitor and an inductor, respectively, or vice versa. For the balun shown in FIG. 8, impedance matching is achieved by requiring:

$$\vert X \vert = \frac{\vert {Z}_{0} \vert}{\sqrt{α}}$$

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description.

The terms used in the following claims should not be construed to limit the invention to the specific embodiments disclosed in the specification and the claims. Instead, the scope of the invention is to be determined entirely by the following claims, which are to be construed in accordance with established doctrines of claim interpretation.

1. An apparatus comprising:
a film bulk acoustic resonator (FBAR) filter having an input and an output; and
an impedance matching unit coupled to one of the input and the output of the FBAR filter.

2. The apparatus of claim 1 wherein the FBAR filter comprises ladder-type FBAR filter.

3. The apparatus of claim 1 wherein the FBAR filter comprises a lattice-type FBAR filter

4. The apparatus of claim 1 wherein the impedance matching unit comprises a shunt capacitor followed by an in-line inductor.

5. The apparatus of claim 1 wherein the impedance matching unit comprises an in-line inductor followed by a shunt capacitor.

6. The apparatus of claim 1 wherein the impedance matching unit comprises a shunt inductor followed by an in-line capacitor.

7. The apparatus of claim 1 wherein the impedance matching unit comprises an in-line capacitor followed by a shunt inductor.

8. The apparatus of claim 1 wherein the impedance matching unit comprises a shunt inductor followed by an in-line inductor.

9. The apparatus of claim 1 wherein the impedance matching unit comprises an in-line inductor followed by a shunt inductor.

10. The apparatus of claim 1 wherein the impedance matching unit comprises a shunt capacitor followed by an in-line capacitor.

11. The apparatus of claim 1 wherein the impedance matching unit comprises an in-line capacitor followed by a shunt capacitor.

12. The apparatus of claim 1 wherein the impedance matching unit comprises a balanced/unbalanced (balun) circuit.

13. The apparatus of claim 1 wherein the impedance matching unit comprises a coil transformer.

14. An apparatus comprising:
a film bulk acoustic resonator (FBAR) filter having an input and an output;
an input impedance matching unit coupled to the input of the FBAR filter; and
an output impedance matching unit coupled to the output of the FBAR filter.

15. The apparatus of claim 14 wherein the input impedance matching unit and the output impedance matching unit have different constructions.

16. The apparatus of claim 14 wherein the input impedance matching unit and the output impedance matching unit have the same construction.

17. The apparatus of claim 14 wherein the impedance matching unit comprises a shunt capacitor followed by an in-line inductor.

18. The apparatus of claim 14 wherein the input impedance matching unit or the output impedance matching unit comprises an in-line inductor followed by a shunt capacitor.

19. The apparatus of claim 14 wherein the input impedance matching unit or the output impedance matching unit comprises a shunt inductor followed by an in-line capacitor.

20. The apparatus of claim 14 wherein the input impedance matching unit or the output impedance matching unit comprises an in-line capacitor followed by a shunt inductor.

21. The apparatus of claim 14 wherein the input impedance matching unit or the output impedance matching unit comprises a balanced/unbalanced (balun) circuit.

22. A system comprising:
an input circuit; and
a filter coupled to the input circuit, the filter comprising:
a film bulk acoustic resonator (FBAR) filter having an input and an output, and
an input impedance matching unit coupled to the input circuit and to the input of the FBAR filter.

23. The system of claim 22, further comprising:
an output circuit; and
an output impedance matching unit coupled to the output circuit and to the output of the FBAR filter.

24. The system of claim 23 wherein the input impedance matching unit and the output impedance matching unit have different constructions.

25. The system of claim 23 wherein the input impedance matching unit and the output impedance matching unit have the same construction.

26. The system of claim 22 wherein the input impedance matching unit or the output impedance matching unit comprises a shunt capacitor followed by an in-line inductor.

27. The system of claim 21 wherein the input impedance matching unit or the output impedance matching unit comprises an in-line inductor followed by a shunt capacitor.

28. The system of claim 21 wherein the input impedance matching unit or the output impedance matching unit comprises a shunt inductor followed by an in-line capacitor.

29. The system of claim 21 wherein the input impedance matching unit or the output impedance matching unit comprises an in-line capacitor followed by a shunt inductor.

30. The apparatus of claim 21 wherein the input impedance matching unit or the output impedance matching unit comprises a balanced/unbalanced (balun) circuit.

31. A process comprising:
providing a film bulk acoustic resonator (FBAR) filter, the FBAR filter having an input impedance and an output impedance;
matching the impedance of an input circuit to the input impedance of the FBAR filter; and
matching the output impedance of the FBAR filter to the impedance of an output circuit.

32. The process of claim 31 wherein matching the impedance of the input circuit to the input impedance of the FBAR filter comprises coupling an impedance matching unit to the input circuit and to the input of the FBAR filter.

33. The process of claim 32 wherein the input impedance matching unit comprises a shunt capacitor followed by an in-line inductor.

34. The process of claim 32 wherein the input impedance matching unit comprises an in-line inductor followed by a shunt capacitor.

35. The process of claim 32 wherein the input impedance matching unit comprises a shunt inductor followed by an in-line capacitor.

36. The process of claim 32 wherein the input impedance matching unit comprises an in-line capacitor followed by a shunt inductor.

37. The process of claim 31 wherein matching the output impedance of the FBAR filter to the impedance of the output circuit comprises coupling an impedance matching unit to the output circuit and to the output of the FBAR filter.

38. The process of claim 37 wherein the output impedance matching unit comprises a shunt capacitor followed by an in-line inductor.

39. The process of claim 37 wherein the output impedance matching unit comprises an in-line inductor followed by a shunt capacitor.

40. The process of claim 37 wherein the output impedance matching unit comprises a shunt inductor followed by an in-line capacitor.

41. The process of claim 37 wherein the output impedance matching unit comprises an in-line capacitor followed by a shunt inductor.

42. The process of claim 37 wherein the output impedance matching unit comprises a balanced/unbalanced (balun) circuit.
